(19) United States
(12) Patent Application Publication
(10) Pub. No.: US 2022/0364300 A1
(43) Pub. Date: Nov. 17, 2022

(54) METHOD FOR MODIFYING CARBON FIBER AND PRODUCT THEREOF

(71) Applicants: ANHUI POLYTECHNIC UNIVERSITY, Wuhu (CN); ZHEJIANG SCI-TECH UNIVERSITY, Hangzhou (CN)

(72) Inventors: Li YANG, Wuhu (CN); Zhenzhen XU, Wuhu (CN); Qingqing NI, Hangzhou (CN); Yuan CHEN, Wuhu (CN)

(21) Appl. No.: 17/878,227

(22) Filed: Aug. 1, 2022

Related U.S. Application Data
(63) Continuation of application No. PCT/CN2021/092646, filed on May 10, 2021.

(30) Foreign Application Priority Data
Apr. 13, 2021 (CN) 2021103940396

(51) Int. Cl. D06M 11/74; C23C 14/35; C23C 14/58; C23C 14/02; C23C 14/06

(52) U.S. Cl. CPC D06M 11/74; C23C 14/35; C23C 14/5806; C23C 14/024; C23C 14/0605; D06M 2101/40

(57) ABSTRACT

A method for modifying carbon fibers and a product thereof are provided. Modified carbon fibers are obtained by heating prepared carbon fibers under an inert atmosphere after magnetron sputtering treatment. The magnetron sputtering treatment takes the prepared carbon fibers as a substrate material and carbon as a target material, and sputtering conditions includes: a vacuum degree of 2×10⁻³ Pa, a distance from the target material to the substrate material of 4 cm, a magnetron sputtering power of 150-350 W, a magnetron sputtering pressure of 0.5-1.6 Pa, a magnetron sputtering duration of 20-60 min, a high purity argon as working gas, and an argon flow rate of 80 mL/min The heating treatment is carried out under conditions including: a heating rate of 5° C./min, a heating temperature of 200-600° C., and a heating duration of 25-40 min.

### CROSS-REFERENCE TO RELATED APPLICATION

This application claims priority to a Chinese Patent Application No. 2021103940396, filed on Apr. 13, 2021, the entire content of which is hereby incorporated by reference.

### TECHNICAL FIELD

The disclosure relates to the field of carbon fiber modification technologies, and in particular to a method for modifying carbon fibers and a product thereof.

### BACKGROUND

As an inorganic carbon material, a carbon fiber is a microcrystalline graphite material obtained by carbonizing and graphitizing inorganic carbon materials. Excellent properties such as high strength and high modulus, good electrical and thermal conductivity, good electromagnetic shielding, and good fatigue resistance are endowed by heating treatment processes including carbonization and graphitization in the process of carbon fiber manufacturing, which is a new reinforced fiber. However, the carbon fiber is brittle with poor toughness and some defects on the fiber surface produced during the preparation process, affecting mechanical properties of the carbon fiber in practical application. Therefore, the carbon fiber is often used as a reinforced material in combination with other materials while is rarely used as a structural material alone, and how to improve surface defects of carbon fiber materials and improve the mechanical properties of the carbon fiber becomes a technical problem to be solved by those skilled in the art.

### SUMMARY

In order to solve the above technical problems, the disclosure provides a method for modifying carbon fibers and a product thereof. According to the disclosure, surfaces of the carbon fibers are improved by magnetron sputtering and heating treatments, and mechanical properties of carbon fibers are also improved.

One of the technical solutions of the disclosure provides a method for modifying carbon fibers, including the following steps: carrying out magnetron sputtering treatment on prepared carbon fibers, and then carrying out heating treatment in an inert atmosphere, to thereby obtain modified carbon fibers; or carrying out heating treatment while carrying out magnetron sputtering treatment of prepared carbon fibers to thereby obtain modified carbon fibers.

In an embodiment, the magnetron sputtering treatment takes the prepared carbon fibers as a substrate material and carbon as a target material, and the magnetron sputtering treatment is carried out under conditions including: a vacuum degree of 2×10⁻³ Pascals (Pa), a distance from the target material to a substrate material of 4 centimeters (cm), a magnetron sputtering power of a range of 150-350 Watts (W), a magnetron sputtering pressure of a range of 0.5-1.6 Pa, a magnetron sputtering duration of a range of 20-60 minutes (min), high-purity argon as working gas, and an argon flow rate of 80 milliliters per minute (mL/min).

The carbon used as the target material of the disclosure is required to have a carbon content above 99.9 percent (%), so as to ensure homogeneity with carbon fibers. In the existing solutions, magnetron sputtering is used to coat surfaces of the carbon fibers, mainly for the purpose of increasing surface roughness and improving the interfacial engagement of the carbon fibers with matrix resin. According to the disclosure, magnetron sputtering is adopted in combination with condition parameter control, in addition to a characteristic that sputtered carbon particles and the carbon fibers are homogeneous, which are utilized to modify surface defects of the carbon fibers. Besides, the heating treatment is used at the same time to make the carbon particles form films on the surfaces of the carbon fibers under the condition of low-temperature heating treatment, the repairing of carbon fiber surfaces is therefore completed and the strength and elongation properties (also referred to as tensile property) of the carbon fibers are improved by utilizing characteristics of film layers.

In an embodiment, a substrate support rotates at a speed of 30 revolutions per minute (r/min) during the magnetron sputtering treatment to make the coating rather uniform.

In an embodiment, the high-purity argon has a purity of 99.999%.

In an embodiment, the method further includes sizing the carbon fibers and then performing acetone treatment on sized carbon fibers before the magnetron sputtering treatment, to thereby obtain the prepared carbon fibers.

In an embodiment, the acetone treatment includes: putting the sized carbon fibers in an acetone solution, treating at 70 degrees Celsius (° C.) for 24 hours (h), rinsing treated carbon fibers alternately with absolute ethanol and deionized water, then drying rinsed carbon fibers at 80° C. for 24 h and cooling.

In an embodiment, the heating treatment is carried out under conditions including: a heating rate of 5° C./min, a heating temperature of a range of 200-600° C., and a heating duration of in a range of 25-40 min.

According to the disclosure, the carbon particles sputtering onto the surfaces of the carbon fibers move to form a new carbon crystal structure under the heating treatment, and after that, cross-sectional morphologies of the carbon films on the surfaces of the modified carbon fibers change significantly, and a typical columnar structure is transformed into a uniform carbon layer structure. The surface defects of original carbon fibers are hence improved. It is found that the tensile strength does not improve significantly under the heating conditions of 600-1,000° C., and the tensile strength of the modified carbon fibers decreases significantly when the heating treatment temperature exceeds 1,000° C., since the carbon film structure is damaged by the high temperature.

In an embodiment, the method further includes before the carrying out heating treatment, carrying out vacuum treatment and then introducing inert gas.

The disclosure also provides a modified carbon fiber obtained by the method for modifying carbon fibers.

Compared with the prior art, the disclosure has beneficial effects as follows.

In the process of carbon fiber production, some defects impairing later utilization of carbon fibers to a certain extent are produced on the surfaces of the carbon fibers. Moreover, the carbon fibers and carbon fiber composites usually have poor tensile elongation at break caused by structural characteristics of carbon fibers, making the material prone to asymptomatic damage during usage. According to the disclosure, magnetron sputtering technology is utilized to sputter the carbon particles made of the same material as the carbon fibers onto the surfaces of the carbon fibers, and the surface defects of the carbon fibers are modified to some extent after the heating treatment. In addition to that, the surfaces of the carbon fibers form dense films under the influence of the heating treatment; the elongation strength of the carbon fibers as being stretched is enhanced due to the membrane structure and the crack transmission properties.

The magnetron sputtering treatment of the carbon fibers can significantly improve the surface morphology of carbon fibers, make up for the surface defects produced in the production process of the carbon fibers, and improve the mechanical properties of the carbon fibers. The carbon particles on the surfaces of the carbon fibers after the magnetron sputtering treatment are heated in the inert environment to form the films under the condition of the low-temperature heating treatment, thus completing the modification of the carbon fibers on the surfaces; and the strength and elongation properties of the carbon fibers are also improved by utilizing the film characteristics. The carbon fibers modified by the disclosure show an increase in tensile strength of 4%-12% and an increase in tensile breaking work of 15%-40%, indicating effectively improved mechanical properties of the carbon fiber.

### BRIEF DESCRIPTION OF DRAWINGS

FIG. 1 shows a surface morphology of a carbon fiber bundle after acetone treatment in Embodiment 1 of the disclosure.

FIG. 2 shows a surface morphology of the carbon fiber bundle after magnetron sputtering treatment in the Embodiment 1 of the disclosure.

FIG. 3 shows a surface morphology of the carbon fiber bundle after the magnetron sputtering treatment and heating treatment in the Embodiment 1 of the disclosure.

FIG. 4 shows a cross-sectional view of the carbon fiber bundle after the magnetron sputtering treatment in the Embodiment 1 of the disclosure.

FIG. 5 shows a cross-sectional view of the carbon fiber bundle after the magnetron sputtering treatment and the heating treatment in the Embodiment 1 of the disclosure.

### DETAILED DESCRIPTION OF EMBODIMENTS

Now various exemplary embodiments of the disclosure will be described in detail. This detailed description should not be taken as a limitation of the disclosure, but should be understood as a more detailed description of some aspects, characteristics, and embodiments of the disclosure.

It should be understood that terms mentioned in the disclosure are only used to describe specific embodiments, and are not used to limit the disclosure. In addition, for numerical ranges in the disclosure, it should be understood that each intermediate value between the upper limit and the lower limit of each of the ranges is also specifically disclosed. Every smaller range between any stated value or the intermediate value within the stated range and any other stated value or the intermediate value within the stated range is also included in the disclosure. The upper and lower limits of these smaller ranges can be independently included or excluded from each of the ranges.

Unless otherwise stated, all technical and scientific terms used herein have the same meanings commonly understood by those skilled in the art to which the disclosure relates. Although the disclosure only describes preferred methods and materials, any methods and materials similar or equivalent to those described herein may be used in the practice or testing of the disclosure. All documents mentioned in this specification are incorporated by reference to disclose and describe the methods and/or materials related to the documents. In case of conflict with any incorporated documents, the contents of this specification shall prevail.

Without departing from the scope or spirit of the disclosure, it is obvious to those skilled in the art that many modifications and changes may be made to the specific embodiments of the disclosure. Other embodiments obtained from the description of the disclosure will be obvious to the skilled person. The specification and embodiment of the disclosure are only exemplary.

As used in the disclosure, the terms “including”, “comprising”, “having”, and “containing” are all open terms, meaning including but not limited to.

### Embodiment 1

(1) A 12 thousand (K) carbon fiber bundle (also referred to as 12 Kc carbon fiber) produced by Toray, Japan is treated in acetone solution at a constant temperature of 70 degrees Celsius (° C.) for 24 hours (h), then rinsed alternately with absolute ethanol and deionized water to remove sizing agent, dust, and oil stain on the fiber surface, and then dried at 80° C. for 24 h and cooled;

(2) the carbon fiber treated in step (1) is used as a substrate material and fixed onto a cardboard in parallel, a carbon target is installed on a cathode plate, the substrate material is placed under a substrate support, and magnetron sputtering is carried out under the following conditions: a sputtering power of 250 Watts (W), a magnetron sputtering pressure of 1 Pascal (Pa), a sputtering duration of 30 minutes, a vacuum degree of back and bottom of 2×10⁻³ Pa, a distance between target material and substrate material of 4 centimeters (cm), and high-purity argon (99.999%) as working gas, an argon flow rate of 80 milliliters per minute (mL/min), and a rotating speed at 30 revolutions per minute (r/min) of the substrate support; and

(3) the carbon fiber treated in step (2) is placed in a vacuum furnace, and after vacuumizing, inert gas (argon) is introduced, and then the temperature is raised to 300° C. at a heating rate of 5° C/min for treatment of 40 min.

The carbon fiber bundle treated after steps (1), (2), and (3) are subjected to surface morphology and tensile testing, and the specific test methods and conditions are as follows:

(1) tensile property test: a single carbon fiber testing method including: the tensile property of the single carbon fiber is tested according to a standard of ASTMD3379; and the tensile property of the carbon fiber bundle is tested by fixing the treated carbon fiber bundle on a reinforcing sheet with 3M super adhesive and then placing in a tensile zone of a universal testing machine, where a loading speed is 2 millimeters per minute (mm/min), a clamping distance is 100 mm, test conditions are 23±2° C. and the relative humidity is 50±10 percent (%);

(2) surface morphology characterization: the surface morphology of carbon fiber is characterized by scanning electron microscope (S-4800II PE-SEM), where the sample is fixed on a sample table with conductive adhesive and subjected to spraying gold for 15 seconds (s), then the gold-sprayed sample is placed on an observation area of a scanning electron microscope, and its surface morphology is observed at 10 kilovolts (kV).

The tensile test shows that the average tensile breaking strength of untreated carbon fiber bundle is 0.802 kilonewtons (kN), and that of carbon fiber treated by magnetron sputtering is 0.8723 kN, the average tensile breaking strength of carbon fiber treated under sputtering power of 250 W, magnetron sputtering pressure of 1 Pa and sputtering duration of 30 min followed by treatment in vacuum furnace at 300° C. for 40 min is 0.878 kN. It is tested that the tensile breaking strength of carbon fiber after magnetron sputtering is also improved to some extent, with a not obviously increased tensile breaking work; while after the heating treatment, the tensile breaking strength and tensile breaking work of modified carbon fiber are obviously improved. In Embodiment 1, the tensile fracture work of untreated carbon fiber is 1.87 kilojoules (kJ), and that of modified carbon fiber bundle is 2.302 kJ.

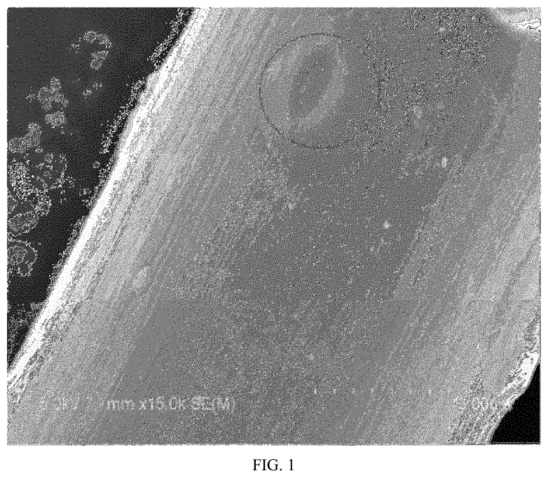

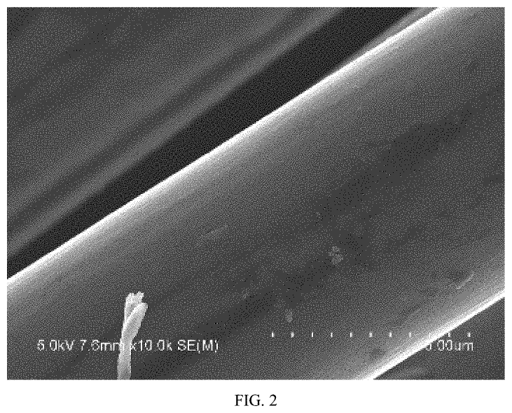

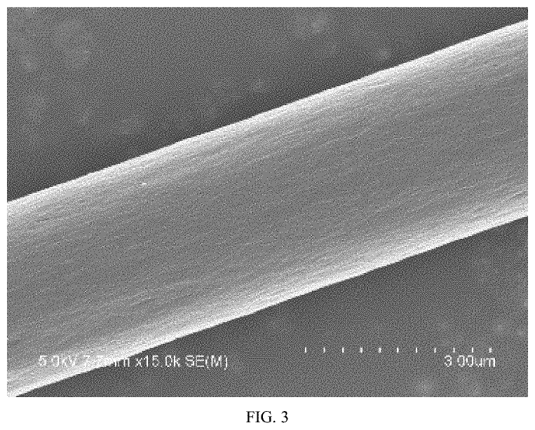

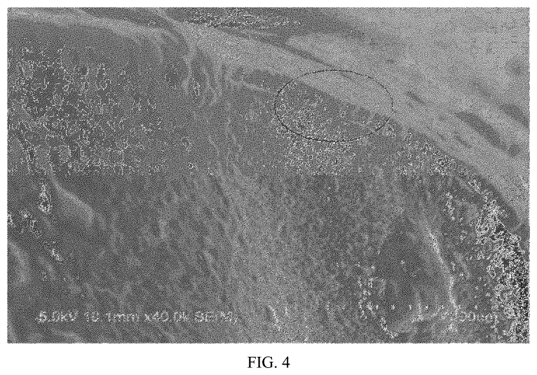

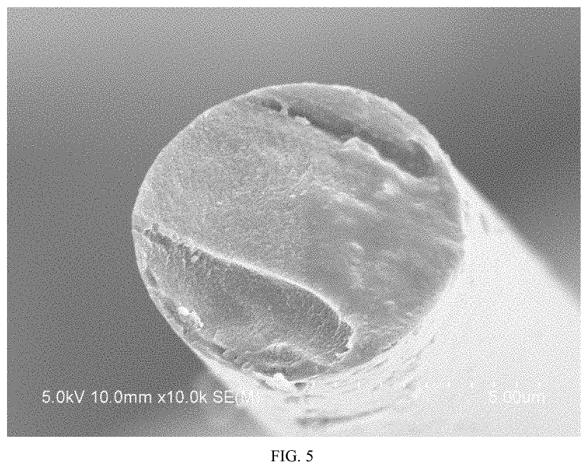

The surface morphology test results are shown in FIGS. 1-5, in which FIG. 1 shows a surface morphology of a carbon fiber bundle after acetone treatment, FIG. 2 shows a surface morphology of the carbon fiber bundle after the magnetron sputtering treatment, FIG. 3 shows a surface morphology of the carbon fiber bundle after the magnetron sputtering treatment and the heating treatment, FIG. 4 shows a cross-sectional view of the carbon fiber bundle after the magnetron sputtering treatment, and FIG. 5 shows a cross-sectional morphology of the carbon fiber bundle after the magnetron sputtering treatment and the heating treatment.

In FIG. 1, there are defects on the surface of untreated carbon fiber produced in the production process. In FIG. 2, the surface of carbon fiber treated by sputtering at 250 W for 30 min shows an obvious film structure. In FIG. 3, there are grooves on the surface of carbon fiber treated by the magnetron sputtering treatment and the heating treatment, which indicates that carbon particles move obviously after the heating treatment. FIG. 4 shows the cross-sectional surface morphology of carbon fiber treated by the magnetron sputtering treatment, where the circled part is the cross-sectional morphology of the carbon film, which shows a clear and typical columnar structure. As shown in FIG. 5, the surface defects of carbon fiber disappeared after the magnetron sputtering treatment and the heating treatment, and there is no obvious film structure, indicating a good combination with carbon fiber is formed. It can be seen from FIGS. 1-5 that the surface defects of the carbon fiber after the modification treatment of the application are obviously improved.

### Embodiment 2

This embodiment is different from Embodiment 1 in that the sputtering power is 250 W, the magnetron sputtering pressure is 1 Pa, the sputtering duration is 45 min, and the final treatment in the vacuum furnace is performed at 200° C. for 40 min The tensile breaking strength of the treated bundle carbon fiber in this embodiment is 0.8956 kN.

### Embodiment 3

This embodiment is different from Embodiment 1 in that the power is 250 W, the magnetron sputtering pressure is 1 Pa, the sputtering time is 45 min, and the heating treatment condition is 300° C. for 40 min The tensile breaking strength of the treated bundle carbon fiber in this embodiment is 0.8533 kN. Embodiment 4

This embodiment is different from Embodiment 1 in that the power is 250 W, the magnetron sputtering pressure is 1 Pa, the sputtering duration is 45 min, and the heating treatment condition is 1,000° C. for 40 min The tensile breaking strength of the treated bundle carbon fiber in this embodiment is 0.158 kN.

### Embodiment 5

(1) A 12K carbon fiber produced by Toray, Japan is treated in acetone solution at a constant temperature of 70° C. for 24 hours, then rinsed alternately with absolute ethanol and deionized water to remove sizing agent, dust, and oil stain on the fiber surface, then dried at 80° C. for 24 hours and cooled;

(2) the carbon fiber treated in step (1) is used as the substrate material and fixed onto a cardboard in parallel, the carbon target material is installed on a cathode plate, and the substrate material is placed under a substrate support, and magnetron sputtering treatment is carried out under the following conditions: a sputtering power of 250 W, a magnetron sputtering pressure of 1 Pa, a sputtering duration of 30 r/min, a heating temperature of 400° C., a heating speed of 5° C/min, a vacuum degree of back and bottom of 2×10⁻³ Pa, a distance between the target material and substrate material of 4 cm, and high-purity argon (99.999%) as working gas, an argon flow rate of 80 mL/min, and a rotating speed of 30 r/min of the substrate support.

The tensile test is carried out on the carbon fiber bundle treated in step (2), and the specific testing methods and conditions are as follows:

Tensile testing: a single carbon fiber testing method including: the tensile property of the single carbon fiber is tested according to a standard of ASTMD3379; and the tensile property of the carbon fiber bundle is tested by fixing the treated bundle carbon fiber on a reinforcing sheet with 3M super adhesive, then placing in a tensile zone of a universal testing machine under a loading speed of 2 mm/min, a clamping distance of 100 mm at 23±2° C. and a relative humidity of 50±10%.

The average tensile breaking strength of the treated carbon fiber bundle is 0.937 kN, and the tensile breaking work of the modified carbon fiber bundle is 1.981 kJ.

The above are only preferred embodiments of the disclosure, and they are not intended to limit the disclosure. Any modifications, equivalent substitutions, and changes made within the spirit and principle of the disclosure should be included in the scope of protection of the disclosure.

What is claimed is:

1. A method for modifying carbon fibers, comprising:
obtaining modified carbon fibers by one selected from a first process and a second process;
wherein the first process comprises: carrying out magnetron sputtering treatment on prepared carbon fibers and then carrying out heating treatment in an inert atmosphere; and
wherein the second process comprises: carrying out the heating treatment while carrying out the magnetron sputtering treatment on the prepared carbon fibers.

2. The method according to claim 1, wherein the magnetron sputtering treatment takes the prepared carbon fibers as a substrate material and carbon as a target material, and the magnetron sputtering treatment is carried out under conditions comprising:
a vacuum degree of 2×10⁻³ Pascals (Pa), a distance from the target material to the substrate material of a range of 2-6 centimeters (cm), a magnetron sputtering power of a range of 150-350 Watts (W), a magnetron sputtering pressure of a range of 0.5-1.6 Pa, a magnetron sputtering duration of a range of 20-60 minutes (min), high-purity argon as working gas, and an argon flow rate of 80 milliliters per minute (mL/min)

3. The method according to claim 2, wherein a substrate support rotates at a speed of 30 revolutions per minute (r/min) during the magnetron sputtering treatment.

4. The method according to claim 2, wherein the high-purity argon has a purity of 99.999 percent (%).

5. The method for modifying carbon fibers according to claim 2, further comprising:
sizing the carbon fibers and then performing acetone treatment on sized carbon fibers before the magnetron sputtering treatment, to thereby obtain the prepared carbon fibers.

6. The method according to claim 5, wherein the performing acetone treatment comprises: putting the sized carbon fibers in an acetone solution, treating at 70 degrees Celsius (° C.) for 24 hours (h), rinsing treated carbon fibers alternately with absolute ethanol and deionized water, then drying rinsed carbon fibers at 80° C. for 24 h and cooling.

7. The method according to claim 1, wherein the heating treatment is carried out under conditions comprising: a heating rate of 5° C/min, a heating temperature of a range of 200-600° C., and a heating duration of in a range of 25-40 min.

8. The method according to claim 7, comprising:
before the carrying out heating treatment, carrying out vacuum treatment, and then introducing inert gas.

9. A modified carbon fiber obtained by the method for modifying carbon fibers according to claim 1.
